(19) United States
(12) Patent Application Publication
(10) Pub. No.: US 2025/0324723 A1
(43) Pub. Date: Oct. 16, 2025

(54) TRANSISTOR STRUCTURE AND MANUFACTURING METHOD THEREOF

(71) Applicant: Powerchip Semiconductor Manufacturing Corporation, Hsinchu (TW)

(72) Inventors: Shang-Shiun Chuang, Hsinchu (TW); Meng-Han Lin, Hsinchu City (TW); Chi-Pei Lu, Hsinchu (TW); Yung-Han Tsai, Hsinchu (TW); Pei-Kang Lee, Hsinchu (TW); Sheng-Yuan Lin, Hsinchu (TW)

(73) Assignee: Powerchip Semiconductor Manufacturing Corporation, Hsinchu (TW)

(21) Appl. No.: 18/779,114

(22) Filed: Jul. 22, 2024

(30) Foreign Application Priority Data
Apr. 15, 2024 (TW) 113114033

(51) Int. Cl. H01L 29/49; H01L 21/302; H01L 29/40; H01L 29/423; H01L 29/66; H01L 29/78

(52) U.S. Cl. CPC H10D 64/671; H10D 30/027; H10D 30/60; H10D 64/01; H10D 64/519; H10D 64/661; H10D 64/665; H01L 21/302

(57) ABSTRACT

A transistor structure and a manufacturing method thereof are provided. In the transistor structure, the substrate has an active area (AA); the gate including a body portion, a first extension portion and a second extension portion is disposed on the substrate in the AA; the first and second extension portions are connected to the body portion extending in a first direction; the first extension portion is located at the first side of the AA and partially overlaps the AA; the second extension portion is located at the second side of the AA and partially overlaps the AA; the material of the first and second extension portions is different from that of the body portion; the first and the second doped regions are disposed in the substrate at two sides of the gate in a second direction; the gate dielectric layer is disposed between the gate and the substrate.

### CROSS-REFERENCE TO RELATED APPLICATION

This application claims the priority benefit of Taiwan application serial no. 113114033, filed on Apr. 15, 2024. The entirety of the above-mentioned patent application is hereby incorporated by reference herein and made a part of this specification.

### BACKGROUND

### Technical Field

The present invention relates to a semiconductor structure and a manufacturing method thereof, and in particular to a transistor structure and a manufacturing method thereof.

### Description of Related Art

In the integrated circuit, the transistor device is one of the main devices. The transistor device may include the gate and the source region and the drain region in the substrate at both sides of the gate. In some transistor devices, the transistor device has a lower channel resistance in the edge region of the gate in the active region than in the central region of the gate in the active region, so a current double hump effect may be easily occurred, which has a negative impact on the electrical properties of the transistor device.

### SUMMARY

The present invention provides a transistor structure and a manufacturing method thereof, in which the current double hump effect may be effectively reduced, thereby avoiding the negative impact of the current double hump effect on the electrical properties of the transistor structure.

The transistor structure of the present invention includes a substrate, a gate, a first doped region, a second doped region and a gate dielectric layer. The substrate has an active area, and the active area has first and second sides opposite to each other. The gate is disposed on the substrate in the active area. The gate includes a body portion, a first extension portion and a second extension portion. The first extension portion and the second extension portion are connected to the body portion. The body portion extends in a first direction. The first extension portion is located at the first side and partially overlaps the active area. The second extension portion is located at the second side and partially overlaps with the active area. The material of the first extension portion and the second extension portion is different from that of the body portion. The first and the second doped regions are located in the active area and disposed in the substrate at two sides of the gate in a second direction intersecting the first direction. The gate dielectric layer is disposed between the gate and the substrate.

In an embodiment of the transistor structure of the present invention, the material of the body portion includes metal, and the material of the first extension portion and the second extension portion includes polysilicon.

In an embodiment of the transistor structure of the present invention, the body portion extends across the active area and extends beyond the active area.

In an embodiment of the transistor structure of the present invention, the first extension portion and the second extension portion are respectively located at opposite sides of the body portion in the second direction.

In an embodiment of the transistor structure of the present invention, the first extension portion and the second extension portion are respectively located at the same side of the body portion in the second direction.

In an embodiment of the transistor structure of the present invention, the first extension portion includes two sub-extension portions, and the two sub-extension portions are respectively located at opposite sides of the body portion in the second direction.

In an embodiment of the transistor structure of the present invention, the second extension portion includes two sub-extension portions, and the two sub-extension portions are respectively located at opposite sides of the body portion in the second direction.

In an embodiment of the transistor structure of the present invention, the entire body portion is located in the active area, the first extension portion and the second extension portion are respectively located at opposite sides of the body portion in the first direction, and widths of the first extension portion and the second extension portion in the second direction is greater than a width of the body portion in the second direction.

The manufacturing method of the transistor structure of the present invention includes the following steps. A substrate is provided, wherein the substrate has an active area, and the active area has a first side and a second side opposite to each other. A gate is formed on the substrate in the active area, wherein the gate includes a body portion, a first extension portion and a second extension portion, the first extension portion and the second extension portion are connected to the body portion, the body portion extends in a first direction, and the first extension portion is located at the first side and partially overlaps the active area, the second extension portion is located at the second side and partially overlaps the active area, and a material of the first extension portion and the second extension portion is different from a material of the body portion. A gate dielectric layer is formed between the gate and the substrate. A first doped region and a second doped region are formed in the substrate at both sides of the gate in a second direction intersecting the first direction.

In an embodiment of the manufacturing method of the transistor structure of the present invention, the material of the body portion includes metal, and the material of the first extension portion and the second extension portion includes polysilicon.

In an embodiment of the manufacturing method of the transistor structure of the present invention, a forming method of the gate includes the following steps. A gate structure is formed on the substrate, wherein the gate structure is composed of the gate dielectric layer and a first gate material layer located on the gate dielectric layer, the gate structure includes an initial body portion, a first initial extension portion and a second initial extension portion, the first initial extension portion and the second initial extension portion are connected to the initial body portion, the initial body portion extends in the first direction, the first initial extension portion is located at the first side and partially overlaps the active area, and the second initial extension portion is located at the second side and partially overlaps the active area. The first gate material layer in the initial body portion is removed to form a gate groove. A second gate material layer is formed in the gate groove, The second gate material layer constitutes the body portion, the first gate material layer in the first initial extension portion constitutes the first extension portion, and the first gate material layer in the second initial extension portion constitutes the second extension portion.

In an embodiment of the manufacturing method of the transistor structure of the present invention, a material of the first gate material layer includes polysilicon, and a material of the second gate material layer includes metal.

In an embodiment of the manufacturing method of the transistor structure of the present invention, the initial body portion extends across the active area and extends beyond the active area.

In an embodiment of the manufacturing method of the transistor structure of the present invention, the first initial extension portion and the second initial extension portion are respectively located at opposite sides of the initial body portion in the second direction.

In an embodiment of the manufacturing method of the transistor structure of the present invention, the first initial extension portion and the initial second extension portion are respectively located at the same side of the initial body portion in the second direction.

In an embodiment of the manufacturing method of the transistor structure of the present invention, the first initial extension portion includes two initial sub-extension portions, and the two initial sub-extension portions are respectively located at opposite sides of the initial body portion in the second direction.

In an embodiment of the manufacturing method of the transistor structure of the present invention, the second initial extension portion includes two initial sub-extension portions, and the two initial sub-extension portions are respectively located at opposite sides of the initial body portion in the second direction.

In an embodiment of the manufacturing method of the transistor structure of the present invention, the entire initial body portion is located in the active area, the first initial extension portion and the second initial extension portion are respectively located at opposite sides of the initial body portion in the first direction, and widths of the first initial extension portion and the second initial extension portion in the second direction are greater than a width of the initial body portion in the second direction.

Based on the above, in the transistor structure of the present invention, the gate has extension portions adjacent to the first side and the second side of the active area, so that the widths of the portions of the gate adjacent to the first side and the second side of the active area may be greater than the width of the remaining portion of the gate. In addition, the extension portion of the gate has greater resistance than the body portion of the gate. In this way, the channel resistance and the threshold voltage (Vt) of the transistor structure in the edge region adjacent to the first side may be improved, and the channel resistance and the threshold voltage of the transistor structure in the edge region adjacent to the second side may be improved. Therefore, the current double hump effect may be effectively reduced, thereby avoiding the negative impact of the current double hump effect on the electrical properties of the transistor structure.

### BRIEF DESCRIPTION OF THE DRAWINGS

FIGS. 1A to 1D are schematic top views of the manufacturing process of the transistor structure of the first embodiment of the present invention.

FIGS. 2A to 2D are schematic cross-sectional views of the manufacturing process of the transistor structure along the section line I-I in FIGS. 1A to 1D.

FIGS. 3A to 3D are schematic cross-sectional views of the manufacturing process of the transistor structure along the section line II-II in FIGS. 1A to 1D.

FIG. 4 is a schematic top view of the transistor structure of the second embodiment of the present invention.

FIG. 5 is a schematic top view of a transistor structure of the third embodiment of the present invention.

FIG. 6 is a schematic top view of the transistor structure of the fourth embodiment of the present invention.

FIG. 7 is a schematic top view of the transistor structure of the fifth embodiment of the present invention.

FIG. 8 is a schematic top view of the transistor structure of the sixth embodiment of the present invention.

FIG. 9 is a schematic top view of the transistor structure of the seventh embodiment of the present invention.

FIG. 10 is a schematic top view of the transistor structure of eighth embodiment of the present invention.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

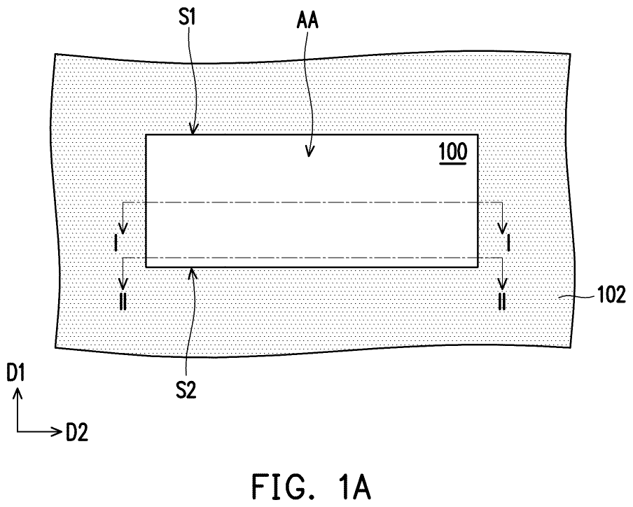

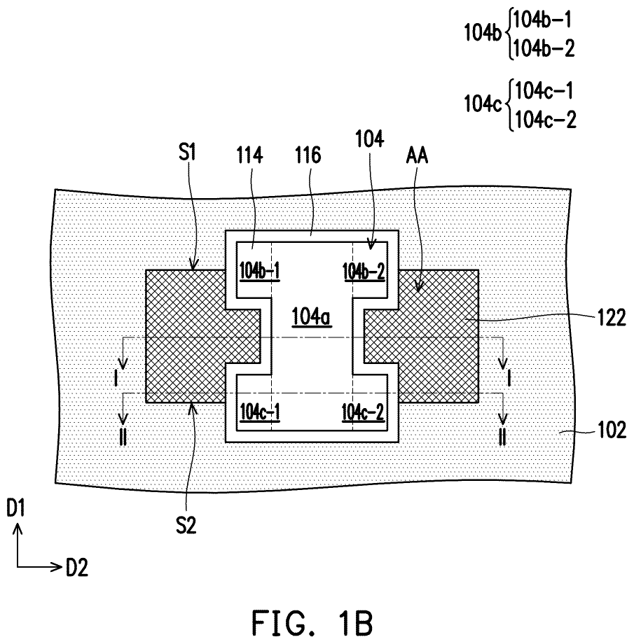

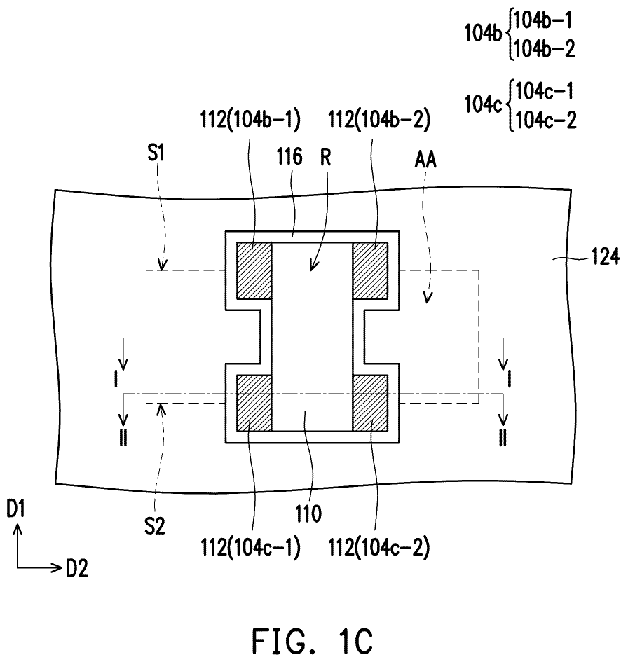

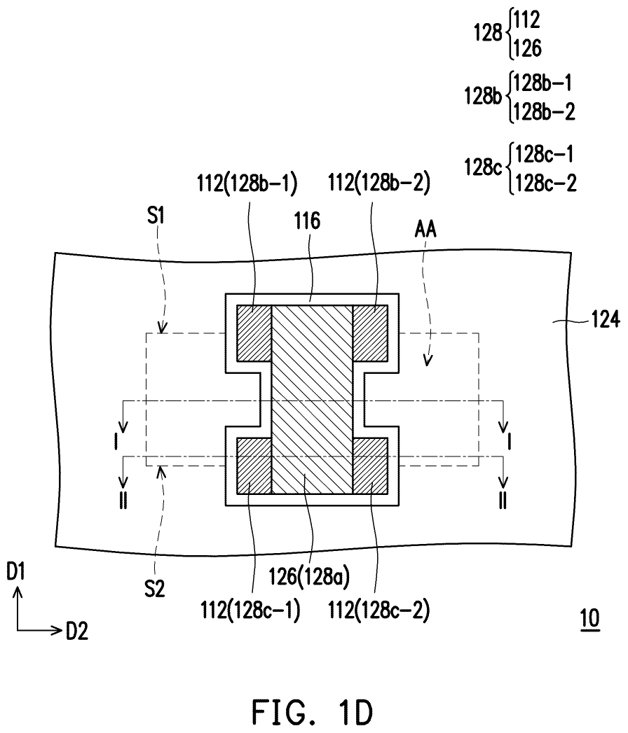

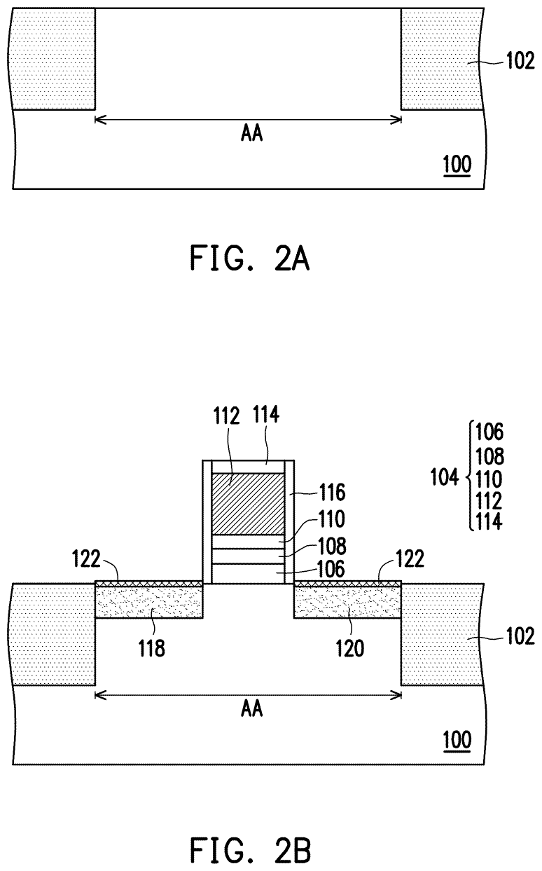

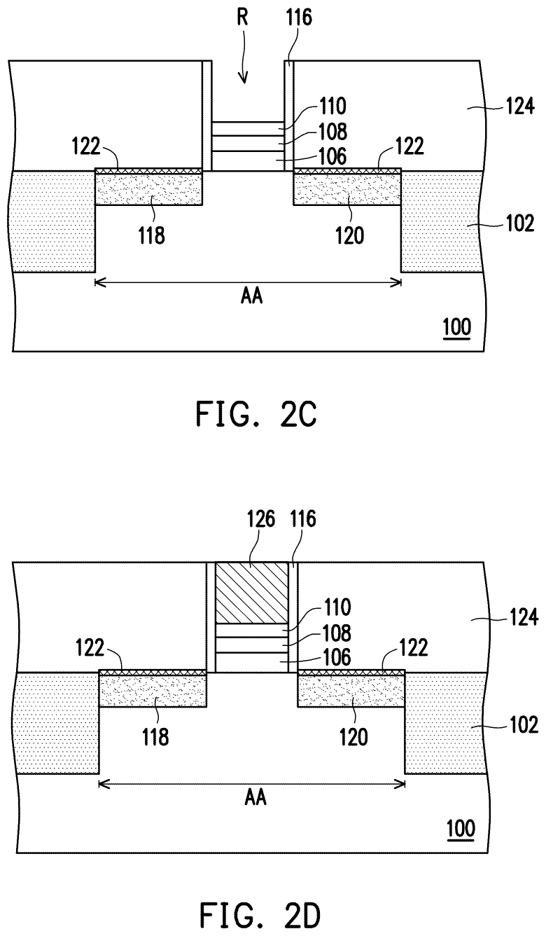

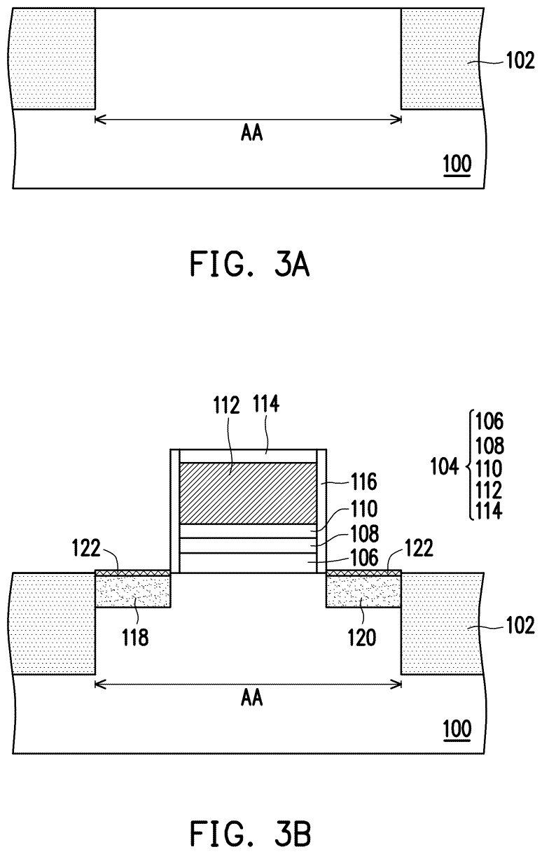

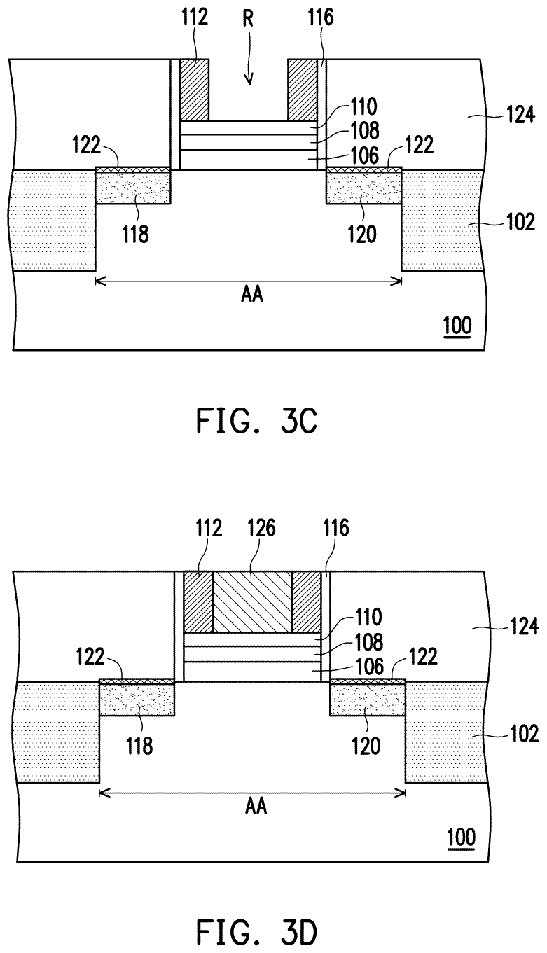

FIGS. 1A to 1D are schematic top views of the manufacturing process of the transistor structure of the first embodiment of the present invention. FIGS. 2A to 2D are schematic cross-sectional views of the manufacturing process of the transistor structure along the section line I-I in FIGS. 1A to 1D. FIGS. 3A to 3D are schematic cross-sectional views of the manufacturing process of the transistor structure along the section line II-II in FIGS. 1A to 1D.

Referring to FIGS. 1A, 2A and 3A, a substrate 100 is provided. In the present embodiment, the substrate 100 is a silicon substrate, but the present invention is not limited thereto. The substrate 100 has an active area AA. In the present embodiment, the active area AA has a first side S1 and a second side S2 opposite to each other in a first direction D1. In detail, an isolation structure 102 is formed in substrate 100 to define the active area AA. The isolation structure 102 may be a shallow trench isolation (STI) structure, and the material of the isolation structure 102 may be silicon oxide. In addition, in some embodiments, after forming the isolation structure 102, an ion implantation process may be performed on the substrate 100 in the active area AA to form a well region in the substrate 100.

Referring to FIGS. 1B, 2B and 3B, a gate structure 104 is formed on the substrate 100 in the active area AA. In the present embodiment, a part of the gate structure 104 is located on the isolation structure 102, so that the gate structure 104 partially overlaps the isolation structure 102 at the first side S1 and the second side S2 respectively.

In detail, in the present embodiment, the gate structure 104 is composed of an interface layer (IL) 106, a gate dielectric layer 108, a capping layer 110, a first gate material layer 112 and a hard mask layer 114. The interface layer 106, the gate dielectric layer 108, the capping layer 110, the first gate material layer 112 and the hard mask layer 114 are located in order on substrate 100 in active area AA and on the isolation structure 102. In addition, the gate structure 104 includes an initial body portion 104a, a first initial extension portion 104b and a second initial extension portion 104c. The first initial extension portion 104b and the second initial extension portion 104c are connected to the initial body portion 104a. The initial body portion 104a extends in the first direction D1, the first initial extension portion 104b is located at the first side S1 and partially overlaps the active area AA, and the second initial extension portion 104b is located at the second side S2 and partially overlaps the active area AA.

In this way, as shown in FIG. 1B, from the top view of the substrate 100, the width of the portions of the gate structure 104 adjacent the first side S1 and the second side S2 may be larger than the width of the remaining portion of the gate structure 104.

In the present embodiment, the initial body portion 104a extends across the active area AA, and extends beyond the active area AA in the first direction D1, and overlaps the isolation structure 102.

The first initial extension portion 104b includes two initial sub-extension portions, namely an initial sub-extension portion 104b-1 and an initial sub-extension portion 104b-2. The initial sub-extension portion 104b-1 and the initial sub-extension portion 104b-2 are respectively located at opposite sides of the initial body portion 104a in a second direction D2 intersecting the first direction D1. One portion of the initial sub-extension portion 104b-1 is located on substrate 100 in active area AA, and the other portion of the initial sub-extension portion 104b-1 is located on the isolation structure 102. One portion of the initial sub-extension portion 104b-2 is located on substrate 100 in active area AA, and the other portion of the initial sub-extension portion 104b-2 is located on the isolation structure 102.

The second initial extension portion 104c includes two initial sub-extension portions, namely an initial sub-extension portion 104c-1 and an initial sub-extension portion 104c-2. The initial sub-extension portion 104c-1 and the initial sub-extension portion 104c-2 are respectively located at opposite sides of the initial body portion 104a in the second direction D2 intersecting the first direction D1. One portion of the initial sub-extension portion 104c-1 is located on substrate 100 in active area AA, and the other portion of the initial sub-extension portion 104c-1 is located on the isolation structure 102. One portion of the initial sub-extension portion 104c-2 is located on substrate 100 in active area AA, and the other portion of the initial sub-extension portion 104c-2 is located on isolation structure 102.

In the present embodiment, the initial sub-extension portion 104b-1, the initial sub-extension portion 104b-2, the initial sub-extension portion 104c-1 and the initial sub-extension portion 104c-2 have the same profile and size, but present invention is not limited thereto.

In the present embodiment, the forming method of the gate structure 104 may include the following steps. First, an interface material layer, a gate dielectric material layer, a capping material layer, a gate material layer and a hard mask material layer are formed on the substrate 100. Then, a patterning process is performed on the interface material layer, the gate dielectric material layer, the capping material layer, the gate material layer and the hard mask material layer.

The material of the interface layer 106 may be silicon oxide. The material of the gate dielectric layer 108 may be a material with a high dielectric constant (high-k material). In the present embodiment, the high-k material usually refers to a dielectric material with a dielectric constant greater than 4 in the present art. The high-k material may be Al₂O₃, Ta₂O₃, TiO₂, Y₂O₃, ZrO₂, HfO₂, La₂O₃, etc., and the present invention does not limit this. The material of the capping layer 110 may be titanium nitride. The material of the first gate material layer 112 may be polysilicon. The material of the hard mask layer 114 may be silicon nitride.

After the gate structure 104 is formed, a spacer 116 is formed on the sidewall of the gate

structure 104. In the present embodiment, the spacer 116 may also be called a seal. The material of the spacer 116 may be silicon nitride. The forming method of the spacer 116 may include the following steps. First, a spacer material layer is conformally formed on the substrate 100. Then, an anisotropic etching process is performed on the spacer material layer until the surface of substrate 100 and the top surface of the hard mask layer 114 are exposed.

After the spacer 116 is formed, an ion implantation process is performed using the spacer 116 and the gate structure 104 as a mask to form a first doped region 118 and a second doped region 120 in the substrate 100 at both sides of the gate structure 104 in the second direction D2. The first doped region 118 and the second doped region 120 may be used as the source and the drain of the transistor structure of the present embodiment. Then, a metal silicide layer 122 may be formed on the surfaces of the first doped region 118 and the second doped region 120. The metal silicide layer 122 may be formed by, for example, performing a self-aligned silicide (salicide) process.

In the present embodiment, since the hard mask layer 114 covers the first gate material layer 112, the metal silicide layer 122 may not be formed on the top surface of the first gate material layer 112, but the present invention is not limited thereto. In other embodiments, after the spacer 116 is formed, the top surface of the first gate material layer 112 may be exposed. Therefore, in addition to being formed on the surfaces of the first doped region 118 and the second doped region 120, the metal silicide layer 122 is also formed on the top surface of the first gate material layer 112.

Referring to FIGS. 1C, 2C and 3C, a dielectric layer 124 is formed on the substrate 100. dielectric layer 124 covers the gate structure 104. The dielectric layer 124 is used as an inter-layer dielectric (ILD) layer. The material of the dielectric layer 124 may be silicon oxide. In addition, in some embodiments, before forming the dielectric layer 124, a contact etching stop layer (CESL) may be conformally formed on the substrate 100.

Next, a part of the dielectric layer 124, a part of the spacer 116 and the hard mask layer 114 are removed to expose the top surface of the first gate material layer 112. The method for removing a part of the dielectric layer 124, a part of the spacer 116 and the hard mask layer 114 is, for example, performing a chemical mechanical polishing (CMP) process.

Afterwards, the first gate material layer 112 in the initial body portion 104a is removed. After removing the first gate material layer 112 in the initial body portion 104a, a gate groove R is formed. In addition, the first gate material layer 112 in the initial sub-extension portion 104b-1, the initial sub-extension portion 104b-2, the initial sub-extension portion 104c-1 and the initial sub-extension portion 104c-2 are remained.

Referring to FIGS. 1D, 2D and 3D, a second gate material layer 126 is formed in the gate groove R. The forming method of the second gate material layer 126 may include the following steps. First, a gate material layer is formed on substrate 100. Then, a chemical mechanical polishing process is performed to remove the gate material layer outside the gate groove R. The material of the second gate material layer 126 may be metal. In this way, the transistor structure 10 of the present embodiment is formed, in which the first gate material layer 112 and the second gate material layer 126 constitute a gate 128 of the transistor structure 10.

As shown in FIG. 1D, the gate 128 is composed of the first gate material layer 112 using polysilicon as the material and the second gate material layer 126 using metal as the material, so the gate 128 is a hybrid gate. Furthermore, in the gate 128, the second gate material layer 126 constitutes the body portion 128a, the first gate material layer 112 in the first initial extension portion 104b constitutes the first extension portion 128b, and the first gate material layer 112 in the second initial extension portion 104c constitutes the second extension portion 128c. The first extension portion 128b and the second extension portion 128c are connected to the body portion 128a.

The body portion 128a extends across the active area AA, and extends beyond the active area AA in the first direction DI to overlap the isolation structure 102. The first extension portion 128b is located at the first side S1 and partially overlaps the active area AA, while the second extension portion 128c is located at the second side S2 and partially overlaps the active area AA. Therefore, from the top view of the substrate 100, the widths of the portions of the gate 128 adjacent to the first side S1 and the second side S2 may be larger than the width of the remaining portion of the gate 128. In addition, the material of the first extension portion 128b and the second extension portion 128c is different from the material of the body portion 128a.

In the present embodiment, the first extension portion 128b includes two sub-extension portions, namely a sub-extension portion 128b-1 and a sub-extension portion 128b-2. The sub-extension portion 128b-1 and the sub-extension portion 128b-2 are respectively located at opposite sides of the body portion 128a in the second direction D2. One portion of the sub-extension portion 128b-1 is located on substrate 100 in the active area AA, and the other portion of the sub-extension portion 128b-1 is located on the isolation structure 102. One portion of the sub-extension portion 128b-2 is located on substrate 100 in the active area AA, and the other portion of the sub-extension portion 128b-2 is located on the isolation structure 102.

In addition, the second extension portion 128c includes two sub-extension portions, namely a sub-extension portion 128c-1 and a sub-extension portion 128c-2. The sub-extension portion 128c-1 and the sub-extension portion 128c-2 are respectively located at opposite sides of the body portion 128a in the second direction D2. One portion of the sub-extension portion 128c-1 is located on substrate 100 in the active area AA, and the other portion of the sub-extension portion 128c-1 is located on the isolation structure 102. One portion of the sub-extension portion 128c-2 is located on substrate 100 in the active area AA, and the other portion of the sub-extension portion 128c-2 is located on the isolation structure 102.

In transistor structure 10, since the widths of the portions of the gate 128 adjacent to the first side S1 and the second side S2 may be larger than the width of the remaining portion of the gate 128, the edge region of the gate 128 adjacent to the first side S1 may have a larger gate length, and the edge region of the gate 128 adjacent to the second side S2 may have a larger gate length. In addition, the first extension portion 128b and the second extension portion 128c have greater resistance than the body portion 128a. In this way, the channel resistance and the threshold voltage of the edge region of the transistor structure 10 adjacent to the first side S1 may be improved, and the channel resistance and the threshold voltage of the edge region of the transistor structure 10 adjacent to the second side S2 may be improved, so the current double hump effect may be effectively reduced, thereby avoiding the negative impact of the current double hump effect on the electrical properties of the transistor structure 10.

In the present embodiment, in the gate 128, the first extension portion 128b includes two sub-extension portions, the second extension portion 128c includes two sub-extension portions, and these sub-extension portions have the same profile and size, but present invention is not limited thereto.

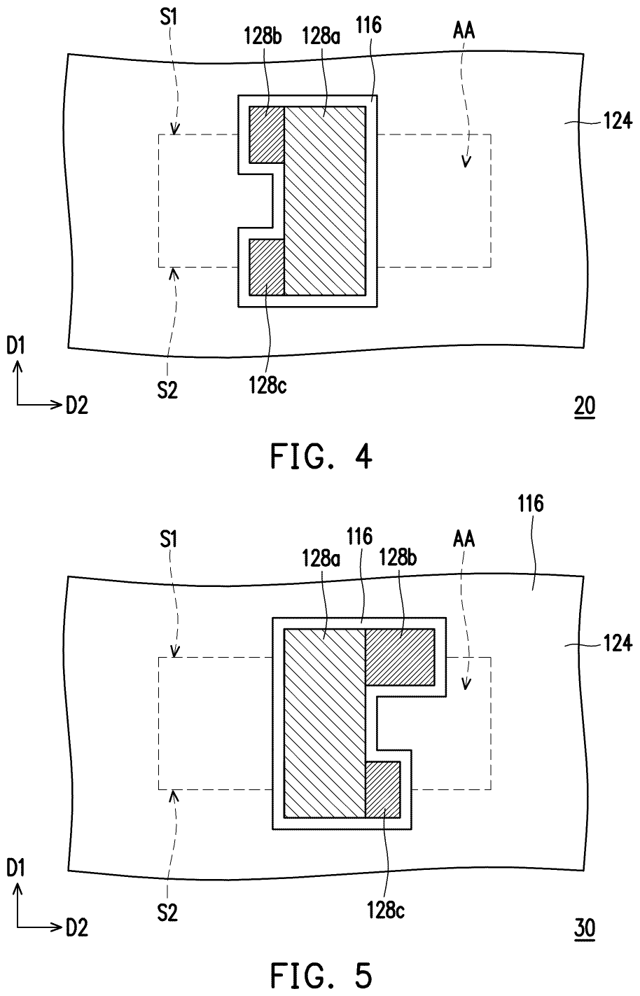

FIG. 4 is a schematic top view of the transistor structure of the second embodiment of the present invention. In the present embodiment, devices that are the same as those in the first embodiment will be represented by the same reference symbols and will not be described again.

Referring to FIG. 4, the difference between the transistor structure 20 of the present embodiment and the transistor structure 10 is that in the transistor structure 20, the first extension portion 128b is a single extension portion, the second extension portion 128c is a single extension portion, and the first extension portion 128b and the second extension portion 128c are located at the same side of the body portion 128a in the second direction D2. Additionally, first extension portion 128b and second extension portion 128c have the same profile and size.

As shown in FIG. 4, in the transistor structure 20, the first extension portion 128b is located at the left side of the body portion 128a, and the second extension portion 128c is located at the left side of the body portion 128a. In this way, the channel resistance and the threshold voltage of the edge region of the transistor structure 20 adjacent to the first side S1 may be improved, and the channel resistance and the threshold voltage of the edge region of the transistor structure 20 adjacent to the second side S2 may be improved, so the current double hump effect may be effectively reduced, thereby avoiding the negative impact of the current double hump effect on the electrical properties of the transistor structure 20.

In other embodiments, the first extension portion 128b may be located at the right side of the body portion 128a, and the second extension portion 128c may be located at the right side of the body portion 128a.

FIG. 5 is a schematic top view of a transistor structure of the third embodiment of the present invention. In the present embodiment, devices that are the same as those in the first embodiment will be represented by the same reference symbols and will not be described again.

Referring to FIG. 5, the difference between the transistor structure 30 of the present embodiment and the transistor structure 10 is that in the transistor structure 30, the first extension portion 128b is a single extension portion, the second extension portion 128c is a single extension portion, and the first extension portion 128b and the second extension portion 128c are located at the same side of the body portion 128a in the second direction D2. In addition, the first extension portion 128b and the second extension portion 128c have different profiles and sizes.

As shown in FIG. 5, in the transistor structure 30, the first extension portion 128b having a larger size is located at the right side of the body portion 128a, and the second extension portion 128c having a smaller size is located at the right side of the body portion 128a. In this way, the channel resistance and the threshold voltage of the edge region of the transistor structure 30 adjacent to the first side S1 may be improved, and the channel resistance and the threshold voltage of the edge region of the transistor structure 30 adjacent to the second side S2 may be improved, so the current double hump effect may be effectively reduced, thereby avoiding the negative impact of the current double hump effect on the electrical properties of the transistor structure 30.

In other embodiments, the first extension portion 128b may be located at the left side of the body portion 128a, and the second extension portion 128c may be located at the left side of the body portion 128a. Additionally, in other embodiments, the first extension portion 128b may have a smaller size and the second extension portion 128c may have a larger size.

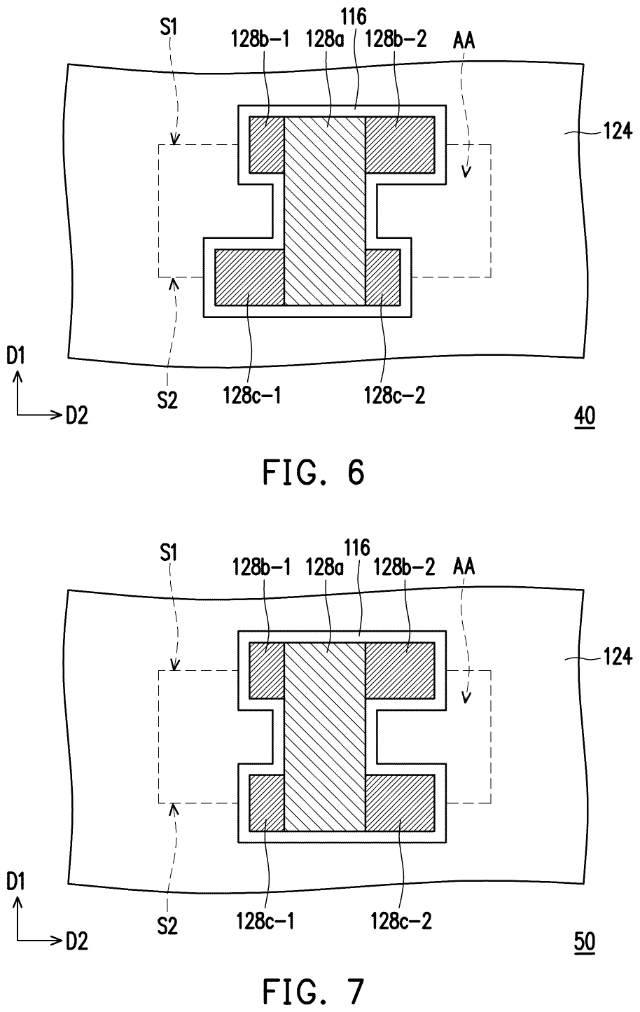

FIG. 6 is a schematic top view of the transistor structure of the fourth embodiment of the present invention. In the present embodiment, devices that are the same as those in the first embodiment will be represented by the same reference symbols and will not be described again.

Referring to FIG. 6, the difference between the transistor structure 40 of the present embodiment and the transistor structure 10 is that in the transistor structure 40, the sub-extension portion 128b-1 and the sub-extension portion 128b-2 of the first extension portion 128b have different profiles and sizes, and the sub-extension portion 128c-1 and the sub-extension portion 128c-2 of the second extension portion 128c have different profiles and sizes. In addition, the sub-extension portion 128b-1 and the sub-extension portion 128c-1 located at the left side of the body portion 128a have different profiles and sizes, and the sub-extension portion 128b-2 and the sub-extension portion 128c-2 located at the right side of the body portion 128a has different profiles and sizes.

In this way, the channel resistance and the threshold voltage of the edge region of the transistor structure 40 adjacent to the first side S1 may be improved, and the channel resistance and the threshold voltage of the edge region of the transistor structure 40 adjacent to the second side S2 may be improved, so the current double hump effect may be effectively reduced, thereby avoiding the negative impact of the current double hump effect on the electrical properties of the transistor structure 40.

FIG. 7 is a schematic top view of the transistor structure of the fifth embodiment of the present invention. In the present embodiment, devices that are the same as those in the first embodiment will be represented by the same reference symbols and will not be described again.

Referring to FIG. 7, the difference between the transistor structure 50 of the present embodiment and the transistor structure 10 is that in the transistor structure 50, the sub-extension portion 128b-1 and the sub-extension portion 128b-2 of the first extension portion 128b have different profiles and sizes, and the sub-extension portion 128c-1 and the sub-extension portion 128c-2 of the second extension portion 128c have different profiles and sizes. In addition, the sub-extension portion 128b-1 and the sub-extension portion 128c-1 located at the left side of the body portion 128a have the same profile and size, and the sub-extension portion 128b-2 and the sub-extension portion 128c-2 located at the right side of the body portion 128a has the same profile and size.

In this way, the channel resistance and the threshold voltage of the edge region of the transistor structure 50 adjacent to the first side S1 may be improved, and the channel resistance and the threshold voltage of the edge region of the transistor structure 50 adjacent to the second side S2 may be improved, so the current double hump effect may be effectively reduced, thereby avoiding the negative impact of the current double hump effect on the electrical properties of the transistor structure 50.

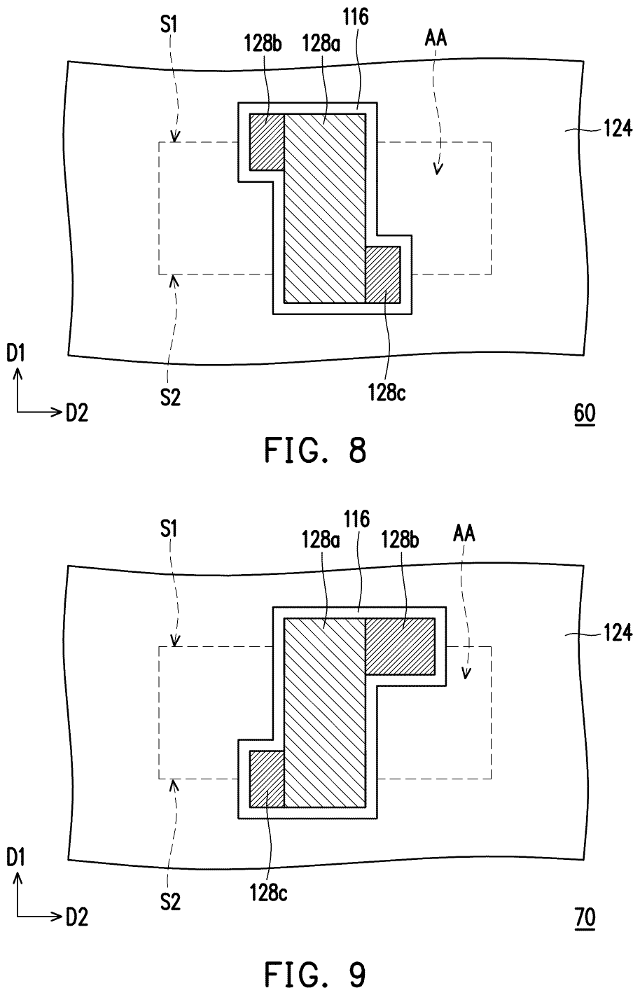

FIG. 8 is a schematic top view of the transistor structure of the sixth embodiment of the present invention. In the present embodiment, devices that are the same as those in the first embodiment will be represented by the same reference symbols and will not be described again.

Referring to FIG. 8, the difference between the transistor structure 60 of the present embodiment and the transistor structure 10 is that in the transistor structure 60, the first extension portion 128b is a single extension portion, the second extension portion 128c is a single extension portion, and the first extension portion 128b and the second extension portion 128c are respectively located at opposite sides of the body portion 128a in the second direction D2. Additionally, the first extension portion 128b and the second extension portion 128c have the same profile and size.

As shown in FIG. 8, in the transistor structure 60, the first extension portion 128b is located at the left side of the body portion 128a, and the second extension portion 128c is located at the right side of the body portion 128a. In this way, the channel resistance and the threshold voltage of the edge region of the transistor structure 60 adjacent to the first side S1 may be improved, and the channel resistance and the threshold voltage of the edge region of the transistor structure 60 adjacent to the second side S2 may be improved, so the current double hump effect may be effectively reduced, thereby avoiding the negative impact of the current double hump effect on the electrical properties of the transistor structure 60.

In other embodiments, the first extension portion 128b may be located to the right side of the body portion 128a, and the second extension portion 128c may be located to the left side of the body portion 128a.

FIG. 9 is a schematic top view of the transistor structure of the seventh embodiment of the present invention. In the present embodiment, devices that are the same as those in the first embodiment will be represented by the same reference symbols and will not be described again.

Referring to FIG. 9, the difference between the transistor structure 70 of the present embodiment and the transistor structure 10 is that in the transistor structure 70, the first extension portion 128b is a single extension portion, the second extension portion 128c is a single extension portion, and the first extension portion 128b and the second extension portion 128c are respectively located at opposite sides of the body portion 128a in the second direction D2. In addition, the first extension portion 128b and the second extension portion 128c have different profiles and sizes.

As shown in FIG. 9, in the transistor structure 70, the first extension portion 128b having a larger size is located at the right side of the body portion 128a, and the second extension portion 128c having a smaller size is located at the left side of the body portion 128a. In this way, the channel resistance and the threshold voltage of the edge region of the transistor structure 70 adjacent to the first side S1 may be improved, and the channel resistance and the threshold voltage of the edge region of the transistor structure 70 adjacent to the second side S2 may be improved, so the current double hump effect may be effectively reduced, thereby avoiding the negative impact of the current double hump effect on the electrical properties of the transistor structure 70.

In other embodiments, the first extension portion 128b may be located at the left side of the body portion 128a, and second extension portion 128c may be located at the right side of the body portion 128a. Additionally, in other embodiments, the first extension portion 128b may have a smaller size and the second extension portion 128c may have a larger size.

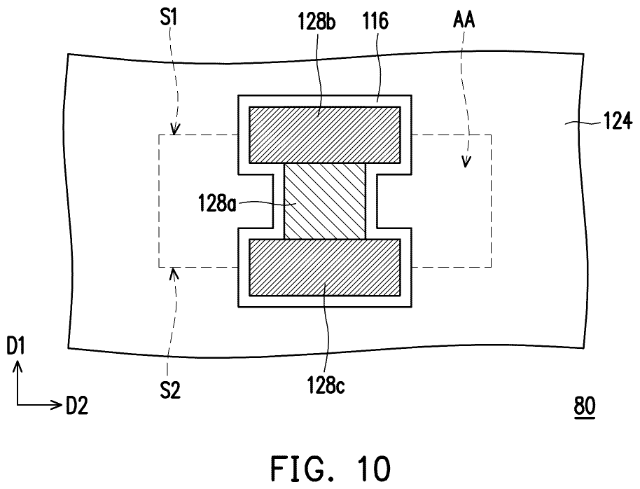

FIG. 10 is a schematic top view of the transistor structure of eighth embodiment of the present invention. In the present embodiment, devices that are the same as those in the first embodiment will be represented by the same reference symbols and will not be described again.

Referring to FIG. 10, the difference between the transistor structure 80 of the present embodiment and the transistor structure 10 is that in the transistor structure 80, the entire body portion 128a is located in the active area AA, and the first extension portion 128b and the second extension portion 128c are located at opposite sides of the body portion 128a in the first direction D1 respectively, and the widths of the first extension portion 128b and the second extension portion 128c in the second direction D2 are greater than the width of the body portion 128a in the second direction D2.

In this way, the channel resistance and the threshold voltage of the edge region of the transistor structure 80 adjacent to the first side S1 may be improved, and the channel resistance and the threshold voltage of the edge region of the transistor structure 80 adjacent to the second side S2 may be improved, so the current double hump effect may be effectively reduced, thereby avoiding the negative impact of the current double hump effect on the electrical properties of the transistor structure 80.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a substrate, having an active area, wherein the active area has a first side and a second side opposite to each other;
a gate, disposed on the substrate in the active area, wherein the gate comprises a body portion, a first extension portion and a second extension portion, the first extension portion and the second extension portion are connected to the body portion, the body portion extends in a first direction, and the first extension portion is located at the first side and partially overlaps the active area, the second extension portion is located at the second side and partially overlaps the active area, and a material of the first extension portion and the second extension portion is different from a material of the body portion;
a first doped region and a second doped region, located in the active area, and disposed in the substrate at both sides of the gate in a second direction intersecting the first direction; and
a gate dielectric layer, disposed between the gate and the substrate.

2. The semiconductor structure of claim 1, wherein the material of the body portion comprises metal, and the material of the first extension portion and the second extension portion comprises polysilicon.

3. The semiconductor structure of claim 1, wherein the body portion extends across the active area and extends beyond the active area.

4. The semiconductor structure of claim 3, wherein the first extension portion and the second extension portion are respectively located at opposite sides of the body portion in the second direction.

5. The semiconductor structure of claim 3, wherein the first extension portion and the second extension portion are respectively located at the same side of the body portion in the second direction.

6. The semiconductor structure of claim 3, wherein the first extension portion comprises two sub-extension portions, and the two sub-extension portions are respectively located at opposite sides of the body portion in the second direction.

7. The semiconductor structure of claim 3, wherein the second extension portion comprises two sub-extension portions, and the two sub-extension portions are respectively located at opposite sides of the body portion in the second direction.

8. The semiconductor structure of claim 1, wherein the entire body portion is located in the active area, the first extension portion and the second extension portion are respectively located at opposite sides of the body portion in the first direction, and widths of the first extension portion and the second extension portion in the second direction is greater than a width of the body portion in the second direction.

9. A manufacturing method of a semiconductor structure, comprising:
providing a substrate, wherein the substrate has an active area, and the active area has a first side and a second side opposite to each other;
forming a gate on the substrate in the active area, wherein the gate comprises a body portion, a first extension portion and a second extension portion, the first extension portion and the second extension portion are connected to the body portion, the body portion extends in a first direction, and the first extension portion is located at the first side and partially overlaps the active area, the second extension portion is located at the second side and partially overlaps the active area, and a material of the first extension portion and the second extension portion is different from a material of the body portion;
forming a gate dielectric layer between the gate and the substrate; and
forming a first doped region and a second doped region in the substrate at both sides of the gate in a second direction intersecting the first direction.

10. The manufacturing method of claim 9, wherein the material of the body portion comprises metal, and the material of the first extension portion and the second extension portion comprises polysilicon.

11. The manufacturing method of claim 9, wherein a forming method of the gate comprises:
forming a gate structure on the substrate, wherein the gate structure is composed of the gate dielectric layer and a first gate material layer located on the gate dielectric layer, the gate structure comprises an initial body portion, a first initial extension portion and a second initial extension portion, the first initial extension portion and the second initial extension portion are connected to the initial body portion, the initial body portion extends in the first direction, the first initial extension portion is located at the first side and partially overlaps the active area, and the second initial extension portion is located at the second side and partially overlaps the active area;
removing the first gate material layer in the initial body portion to form a gate groove; and
forming a second gate material layer in the gate groove,
wherein the second gate material layer constitutes the body portion, the first gate material layer in the first initial extension portion constitutes the first extension portion, and the first gate material layer in the second initial extension portion constitutes the second extension portion.

12. The manufacturing method of claim 11, wherein a material of the first gate material layer comprises polysilicon, and a material of the second gate material layer comprises metal.

13. The manufacturing method of claim 11, wherein the initial body portion extends across the active area and extends beyond the active area.

14. The manufacturing method of claim 13, wherein the first initial extension portion and the second initial extension portion are respectively located at opposite sides of the initial body portion in the second direction.

15. The manufacturing method of claim 13, wherein the first initial extension portion and the initial second extension portion are respectively located at the same side of the initial body portion in the second direction.

16. The manufacturing method of claim 13, wherein the first initial extension portion comprises two initial sub-extension portions, and the two initial sub-extension portions are respectively located at opposite sides of the initial body portion in the second direction.

17. The manufacturing method of claim 13, wherein the second initial extension portion comprises two initial sub-extension portions, and the two initial sub-extension portions are respectively located at opposite sides of the initial body portion in the second direction.

18. The manufacturing method of claim 11, wherein the entire initial body portion is located in the active area, the first initial extension portion and the second initial extension portion are respectively located at opposite sides of the initial body portion in the first direction, and widths of the first initial extension portion and the second initial extension portion in the second direction are greater than a width of the initial body portion in the second direction.
